(19) United States
(12) Patent Application Publication
(10) Pub. No.: US 2023/0091210 A1
(43) Pub. Date: Mar. 23, 2023

(54) SEMICONDUCTOR MEMORY DEVICE

(71) Applicant: Kioxia Corporation, Tokyo (JP)

(72) Inventor: Masakazu GOTO, Moriya Ibaraki (JP)

(73) Assignee: Kioxia Corporation, Tokyo (JP)

(21) Appl. No.: 17/693,903

(22) Filed: Mar. 14, 2022

(30) Foreign Application Priority Data
Sep. 17, 2021 (JP) 2021-152580

(51) Int. Cl. H01L 27/11582; H01L 27/11556

(52) U.S. Cl. CPC H01L 27/11582; H01L 27/11556

(57) ABSTRACT

According to one embodiment, a semiconductor memory device includes: a stacked body in which a plurality of conductive layers and a plurality of insulating layers are alternately stacked; and a pillar including a channel layer extending in a stacking direction of the plurality of conductive layers in the stacked body, a memory layer provided on a side surface of the channel layer, and a cap layer provided on the channel layer, the cap layer being connected to an upper layer wiring of the stacked body, wherein the channel layer extends into the stacked body at least from a height position of an uppermost conductive layer of the plurality of conductive layers, and a grain size of crystal contained in the channel layer is larger than a grain size of crystal contained in the cap layer.

### CROSS-REFERENCE TO RELATED APPLICATIONS

This application is based upon and claims the benefit of priority from Japanese Patent Application No. 2021-152580, filed on Sep. 17, 2021; the entire contents of which are incorporated herein by reference.

### FIELD

Embodiments described herein relate generally to a semiconductor memory device.

### BACKGROUND

In three-dimensional nonvolatile memories, for example, pillars penetrate in a stacked body in which a plurality of conductive layers are stacked, and memory cells are formed at intersections between the pillars and at least some of the conductive layers. It is desirable for the memory cells to have a steep threshold voltage distribution and to obtain a large cell current.

### BRIEF DESCRIPTION OF THE DRAWINGS

FIGS. 1A to 1D are cross-sectional diagrams illustrating an example of a configuration of a semiconductor memory device according to an embodiment;

FIGS. 2A to 2F are cross-sectional diagrams along the Y direction illustrating an example of a procedure of a method for manufacturing the semiconductor memory device according to the embodiment;

FIGS. 3A to 3F are cross-sectional diagrams along the Y direction illustrating an example of the procedure of the method for manufacturing the semiconductor memory device according to the embodiment;

FIGS. 4A to 4F are cross-sectional diagrams along the Y direction illustrating an example of the procedure of the method for manufacturing the semiconductor memory device according to the embodiment;

FIGS. 5A to 5F are cross-sectional diagrams along the Y direction illustrating an example of the procedure of the method for manufacturing the semiconductor memory device according to the embodiment; and

FIG. 6 is a cross-sectional diagram illustrating an example of a configuration of a semiconductor memory device according to a modification of the embodiment.

### DETAILED DESCRIPTION

A semiconductor memory device according to an embodiment includes: a stacked body in which a plurality of conductive layers and a plurality of insulating layers are alternately stacked; and a pillar including a channel layer extending in a stacking direction of the plurality of conductive layers in the stacked body, a memory layer provided on a side surface of the channel layer, and a cap layer provided on the channel layer, the cap layer being connected to an upper layer wiring of the stacked body, wherein the channel layer extends into the stacked body at least from a height position of an uppermost conductive layer of the plurality of conductive layers, and a grain size of crystal contained in the channel layer is larger than a grain size of crystal contained in the cap layer.

Hereinafter, the present invention will be described in detail with reference to the drawings. Note that the present invention is not limited by the following embodiments. In addition, constituent elements in the following embodiments include those that can be easily assumed by those skilled in the art or those that are substantially the same.

### Example of Configuration of Semiconductor Memory Device

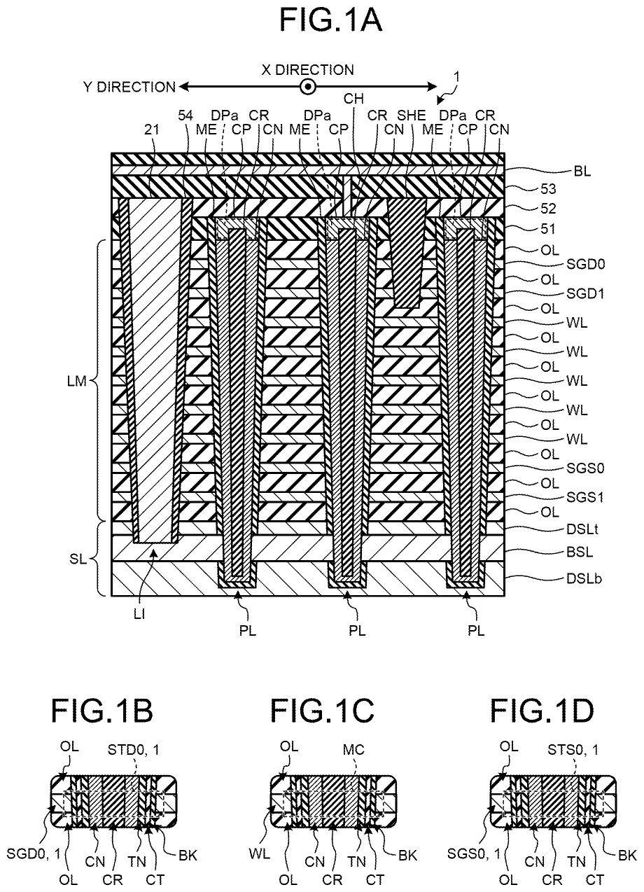

FIGS. 1A to 1D are cross-sectional diagrams illustrating an example of a configuration of a semiconductor memory device 1 according to an embodiment. FIG. 1A is a cross-sectional diagram illustrating an entire structure of pillars PL of the semiconductor memory device 1. FIG. 1B is an enlarged cross-sectional diagram of a pillar PL near a select gate line SGD0 or SGD1, FIG. 1C is an enlarged cross-sectional diagram of a pillar PL near a word line WL, and FIG. 1D is an enlarged cross-sectional diagram of a pillar PL near a select gate line SGS0 or SGS1.

As illustrated in FIG. 1A, the semiconductor memory device 1 includes a source line SL, a stacked body LM, insulating layers 51 to 53, and a bit line BL. Note that, in the present specification, a direction toward the source line SL on the source side is defined as a downward direction of the semiconductor memory device 1, and a direction toward the bit line BL on the drain side is defined as an upward direction of the semiconductor memory device 1.

The source line SL as a conductive film is provided at a lower position of the stacked body LM, and is a stacked film in which a lower source line DSLb, an intermediate source line BSL, and an upper source line DSLt are stacked in this order from the lower side. The lower source line DSLb, the intermediate source line BSL, and the upper source line DSLt are, for example, conductive polysilicon layers or the like.

The stacked body LM has a configuration in which a plurality of word lines WL and a plurality of insulating layers OL are alternately stacked one by one. Additionally, in the stacked body LM, a plurality of select gate lines SGD and SGS and a plurality of insulating layers OL are alternately stacked one by one. One or more select gate lines SGD are provided above the uppermost word line WL, and one or more select gate lines SGS are provided below the lowermost word line WL.

The stacked body LM has a configuration in which a plurality of word lines WL and a plurality of select gate lines SGD and SGS are stacked, in between of which a plurality of insulating layers OL are stacked one by one. One or more select gate lines SGD are provided above the uppermost word line WL, and one or more select gate lines SGS are provided below the lowermost word line WL.

The word lines WL as a plurality of conductive layers and the select gate lines SGD and SGS as a plurality of conductive layers are, for example, tungsten layers, molybdenum layers, or the like. The insulating layers OL are, for example, silicon oxide layers or the like. Note that, in the example of FIG. 1A, five word lines WL are provided in the stacked body LM. In addition, two select gate lines SGD1 and SGD0 are provided in this order from the word line WL side. In addition, two select gate lines SGS1 and SGS0 are provided in this order from the source line side. However, the number of layers of the word lines WL and the select gate lines SGD and SGS is arbitrary regardless of the example of FIG. 1A.

On the stacked body LM, the insulating layers 51 to 53 are stacked in this order. The bit line BL corresponding to an upper layer wiring of the stacked body LM is provided in the insulating layer 53. The insulating layers 51 to 53 are, for example, silicon oxide layers or the like, and the bit line BL is a metal layer.

The stacked body LM is provided with a plurality of plate-like contacts LI extending in the stacking direction of each layer of the stacked body LM and extending in the direction along the X direction as the first direction along each layer of the stacked body LM. The plurality of plate-like contacts LI penetrate the insulating layers 52 and 51, the stacked body LM, and the upper source line DSLt and reach the intermediate source line BSL at positions separated from each other in the Y direction as the second direction intersecting the X direction. In this manner, the stacked body LM is divided in the Y direction by the plurality of plate-like contacts LI.

Insulating layers 54 such as silicon oxide layers are provided on side walls of each of the plate-like contacts LI. The inside of the insulating layers 54 is filled with a conductive layer 21 such as a tungsten layer. The conductive layer 21 of each of the plate-like contacts LI is connected to the upper layer wiring by a plug or the like (not illustrated). In addition, the lower end portion of the conductive layer 21 is connected to the intermediate source line BSL.

With the above configuration, the plate-like contacts LI function as, for example, source line contacts. However, instead of the plate-like contacts LI, insulating layers or the like not having a function as source line contacts may divide the stacked body LM in the Y direction.

A separation layer SHE penetrating the select gate lines SGD0 and SGD1 and extending in the direction along the X direction is provided between two plate-like contacts LI adjacent to each other in the Y direction. The separation layer SHE includes, for example, an insulating layer such as a silicon oxide layer, and penetrates one or more conductive layers including the uppermost conductive layer of the stacked body LM, thereby separating these conductive layers in the Y direction between the two plate-like contacts LI and partitioning them into the patterns of the select gate lines SGD.

In addition, between two plate-like contacts LI, a plurality of pillars PL are provided to be dispersed in, for example, a staggered manner when viewed from the stacking direction of the stacked body LM. Each of the pillars PL includes a channel layer CN, a cap layer CP, a memory layer ME, and a core layer CR, and penetrates through the insulating layer 51, the stacked body LM, the upper source line DSLt, and the intermediate source line BSL to reach the lower source line DSLb.

The channel layer CN as a second region extends in the stacked body LM in the stacking direction of the stacked body LM. More specifically, the channel layer CN extends into the stacked body LM at least from the height position of the uppermost select gate line SGD0 of the stacked body LM, and reaches the lower source line DSLb.

The cap layer CP as a first region is provided on the channel layer CN. In other words, the cap layer CP extends from a position higher than the uppermost select gate line SGD0 of the stacked body LM to the upper end portion of the pillar PL.

The channel layer CN and the cap layer CP are semiconductor layers such as silicon layers. The crystal of silicon or the like contained in the channel layer CN has a larger grain size than the crystal of silicon or the like contained in the cap layer CP, for example.

Such comparison of the grain sizes of the crystals is based on, for example, the average grain size of the crystals. The average grain size of crystals is, for example, an average of grain sizes of crystals present per unit volume, with the maximum diameter of each crystal as the grain size of each crystal.

The crystals in the channel layer CN have, for example, an average grain size of 100 nm or more, and more preferably, the channel layer CN may be a substantially single crystal silicon layer. The average grain size of the cap layer CP is less than 100 nm, and the cap layer CP may be, for example, a polysilicon layer having an average grain size of 20 nm or less. The cap layer CP may be a layer in which polysilicon and amorphous silicon are mixed.

In addition, a dopant DPa such as arsenic is diffused in the crystal of the cap layer CP, and the cap layer CP is connected to the bit line BL via a plug CH provided in the insulating layers 53 and 52 at the upper end portion thereof. Since the dopant DPa is diffused in the cap layer CP, the contact resistance between the cap layer CP and the plug CH can be reduced. However, the dopant DPa in the cap layer CP may be other N-type impurities such as phosphorus other than arsenic.

The core layer CR as a core material extending in the stacking direction of the stacked body LM is provided at the center portion of the pillar PL, and the channel layer CN described above is provided so as to cover the side surface and the lower end portion of the core layer CR. The height position of the upper end portion of the core layer CR is different from, for example, the height position of the upper end portion of the channel layer CN, and the upper end portion of the core layer CR protrudes into, for example, the cap layer CP. The core layer CN is, for example, an insulating layer such as a silicon oxide layer.

The layer thickness of the channel layer CN covering the core layer CR is preferably, for example, 5 nm or less. As a result, the depletion layer can be made thinner than the length in the stacking direction of the channel layer CN corresponding to the gate length, and the short channel effect can be suppressed.

The memory layer ME is provided on a side surface of the channel layer CN. More specifically, as illustrated in FIGS. 1B to 1D, the memory layer ME has a stacked structure in which a block insulating layer BK, a charge trap layer CT, and a tunnel insulating layer TN are stacked in this order from the outer peripheral side of the pillar PL. The block insulating layer BK and the tunnel insulating layer TN are, for example, silicon oxide layers or the like, and the charge trap layer CT is, for example, a silicon nitride layer, a silicon oxynitride layer, or the like.

As described above, the memory layer ME covers the side surface of the channel layer CN, reaches the lower source line DSLb, and also covers the lower end portion of the channel layer CN. However, the memory layer ME is not provided at the depth position of the intermediate source line BSL in the source line SL, and the intermediate source line BSL is in contact with the channel layer CN. As a result, the channel layer CN is connected to the source line SL via the intermediate source line BSL at the side surface.

With the above configuration, a plurality of memory cells MC arranged at the height positions of the word lines WL are formed on the side surface of the pillar PL. In this manner, the semiconductor memory device 1 is configured as, for example, a three-dimensional nonvolatile memory in which the memory cells MC are three-dimensionally arranged.

FIG. 1C illustrates a state in which a memory cell MC is formed at a height position facing a word line WL on the side surface of the pillar PL. When a predetermined voltage is applied via the word line WL, data is written to or read from the memory cell MC.

In other words, when “H” level data is written to the memory cell MC, a write voltage is applied to the connected word line WL. At this time, a ground potential is supplied to the channel layer CN to form a channel, and electrons in the channel pass through the tunnel insulating layer TN and are injected and trapped in the charge trap layer CT. As a result, the threshold voltage Vth of the memory cell MC increases, and the “H” level data is written.

When the “L” level data is written to the memory cell MC, the channel of the channel layer CN is brought into a floating state, so that electrons are not injected into the charge trap layer CT, and a state in which the “L” level data is written while the threshold voltage Vth of the memory cell MC remains low is maintained.

When reading data from the memory cell MC, a read voltage is applied to the connected word line WL. The read voltage is a voltage at which the memory cell MC holding the “L” level data is turned on and the memory cell MC holding the “H” level data is not turned on. Therefore, if the cell current flows to the bit line BL, it means that the “L” level data is read, and if the cell current does not flow to the bit line BL, it means that the “H” level data is read.

As illustrated in FIG. 1B, on the side surface of the pillar PL, select gates STD0 and STD1 are formed at height positions facing the select gate lines SGD0 and SGD1, respectively. As illustrated in FIG. 1D, on the side surface of the pillar PL, select gates STS0 and STS1 are formed at height positions facing the select gate lines SGS0 and SGS1, respectively.

When a predetermined voltage is applied via the select gate lines SGD and SGS, the select gates STD and STS are turned on or off, and the memory cells MC of the pillars PL to which the select gates STD and STS belong enter a selected state or a non-selected state.

The stacked body LM includes, for example, a stepped portion (not illustrated) in which a plurality of word lines WL and select gate lines SGD and SGS are extended stepwise. The individual word lines WL and the select gate lines SGD and SGS in the stepped portion are connected to a peripheral circuit via an upper layer wiring (not illustrated). The memory cells MC of the pillars PL are connected to the peripheral circuit via the above-described bit line BL.

The peripheral circuit includes, for example, a transistor (not illustrated) and the like, and is provided below, above, or the like the stacked body LM. By controlling the voltages applied to the word lines WL and the select gate lines SGD and SGS, the peripheral circuit contributes to the operations of the memory cells MC and the select gates STD and STS. In addition, the peripheral circuit senses a cell current flowing through the bit line BL and reads data from the memory cell MC.

(Method for Manufacturing Semiconductor Memory Device)

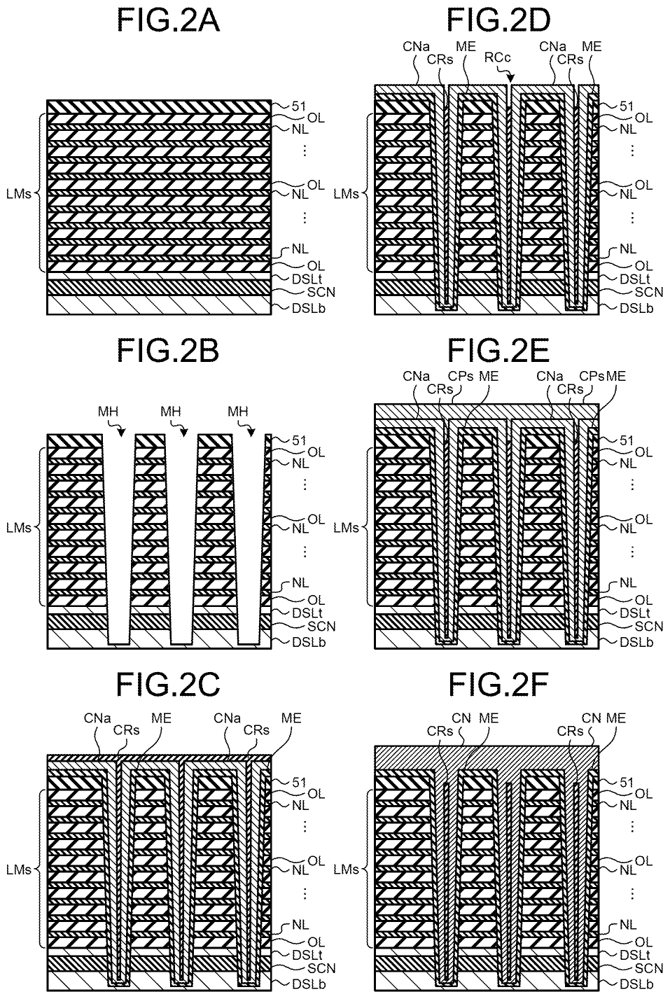

Next, an example of a method for manufacturing the semiconductor memory device 1 according to the embodiment will be described with reference to FIGS. 2A to 5F. FIGS. 2A to 5F are cross-sectional diagrams along the Y direction illustrating an example of the procedure of the method for manufacturing the semiconductor memory device 1 according to the embodiment.

As illustrated in FIG. 2A, a lower source line DSLb, an intermediate layer SCN, and an upper source line DSLt are formed in this order. The intermediate layer SCN is, for example, a sacrificial layer such as a silicon nitride layer, and is later replaced with a conductive polysilicon layer or the like to form the intermediate source line BSL.

In addition, a stacked body LMs in which a plurality of insulating layers NL and a plurality of insulating layers OL are alternately stacked one by one is formed on the upper source line DSLt. The insulating layers NL are sacrificial layers such as silicon nitride layers, for example, and are later replaced with tungsten layers, molybdenum layers, or the like to form the word lines WL and the select gate lines SGD and SGS. An insulating layer 51 is formed on the stacked body LMs.

As illustrated in FIG. 2B, memory holes MH that penetrate the insulating layer 51, the stacked body LMs, the upper source line DSLt, and the intermediate layer SCN and reach the lower source line DSLb are formed.

As illustrated in FIG. 2C, a memory layer ME in which the block insulating layer BK, the charge trap layer CT, and the tunnel insulating layer TN (see FIGS. 1B to 1D) are stacked in this order is formed on the side walls and the bottom surfaces of the memory holes MH. The memory layer ME is also formed on the upper surface of the insulating layer 51.

In addition, a channel layer CNa is formed on the side wall and the bottom surface of the memory hole MH with the memory layer ME interposed therebetween. The channel layer CNa is an amorphous silicon layer or the like that is crystallized later to become the channel layer CN. The channel layer CNa is also formed on the upper surface of the insulating layer 51 with the memory layer ME interposed therebetween.

In addition, the inside of the channel layer CNa of the memory holes MH is filled with a core layer CRs. The core layer CRs is, for example, a sacrificial layer such as a silicon oxide layer, and is removed in a later process. The core layer CRs is also formed on the upper surface of the insulating layer 51 with the channel layer CNa and the memory layer ME interposed therebetween.

As illustrated in FIG. 2D, the core layer CRs is etched back and removed from the upper surface of the insulating layer 51 and the upper surfaces of the memory holes MH. As a result, the channel layer CNa is exposed on the upper surface of the insulating layer 51. In addition, upper end portions of core layers CRs are located at a predetermined depth in the memory holes MH, and concave portions RCc are formed above the core layers CRs.

The concave portions RCc in the memory holes MH are obtained, for example, by continuing over-etching for a predetermined time even after the core layer CRs on the upper surface of the insulating layer 51 is removed.

As illustrated in FIG. 2E, a cap layer CPs covering the channel layer CNa on the upper surface of the insulating layer 51 is formed. The cap layer CPs is, for example, a sacrificial layer such as an amorphous silicon layer, and is removed in a later process. The concave portions RCc in the memory holes MH are also filled with the cap layer CPs.

As illustrated in FIG. 2F, the channel layer CNa and the cap layer CPs are crystallized by, for example, an annealing treatment or the like to form the channel layer CN. In the annealing treatment, for example, a MILC technique or the like may be used in combination in order to promote crystallization.

Note that, at this point, the channel layer CNa is covered with the memory layer ME at the depth positions of the upper source line DSLt and the lower source line DSLb, and is not in contact with the upper source line DSLt and the lower source line DSLb which are, for example, polysilicon layers or the like. For this reason, a relatively homogeneous channel layer CN having substantially single crystal is easily obtained.

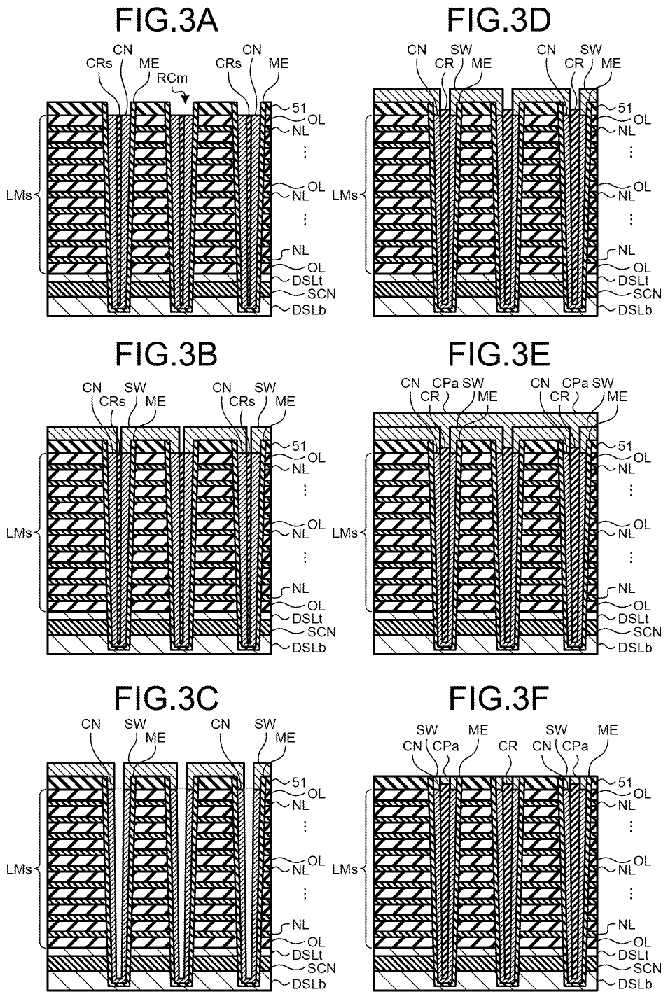

As illustrated in FIG. 3A, the channel layer CN and the memory layer ME are etched back and removed from the upper surface of the insulating layer 51. As a result, the upper surface of the insulating layer 51 is exposed. At this time, channel layers CN and core layers CRs are etched back also in the memory holes MH. As a result, the upper end portions of the channel layers CN and the core layers CRs are located at a predetermined depth in the memory holes MH, and concave portions RCm are formed above the channel layers CN and the core layers CRs.

The concave portions RCm in the memory holes MH are obtained, for example, by continuing over-etching for a predetermined time even after the channel layer CN on the upper surface of the insulating layer 51 is removed. At this time, the upper end portions of the channel layers CN and the core layers CRs are maintained at a height position above at least the uppermost insulating layer NL of the stacked body LMs by controlling the over-etching time or the like.

As illustrated in FIG. 3B, sidewall layers SW covering the upper surface of insulating layer 51 are formed. The sidewall layers SW are also formed in the concave portions RCm at the upper end portions of the memory holes MH so as to cover the side walls of the memory holes MH, and protect the memory layers ME in the slimming process of the channel layers CN described later. The sidewall layers SW are, for example, amorphous silicon layers or the like. Note that the layer thickness of the sidewall layers SW is adjusted so that the concave portions RCm are not completely closed by controlling the process time and the like.

As illustrated in FIG. 3C, by wet etching, isotropic dry etching, or the like, the core layers CRs in the memory holes MH are removed and the channel layers CN are thinned. At this time, the memory layers ME on the side walls of the memory holes MH are protected by the sidewall layers SW. Note that the slimming process described above is preferably performed such that the channel layers CN have a layer thickness of, for example, 5 nm or less.

In this manner, by initially forming the thick channel layer CNa and performing the annealing treatment or the like, the crystallization of the channel layer CNa is easily promoted. In addition, by slimming the crystallized channel layer CN, the depletion layer can be thinned with respect to the gate length as described above, and the short channel effect can be suppressed.

As illustrated in FIG. 3D, the core layers CRs are removed, and gaps in the memory holes MH created by slimming the channel layers CN are filled with insulating layers or the like to form the core layers CR. At this time, the height position of the upper end portions of the core layers CR may not be equal to the height position of the upper end portions of the channel layers CN, and for example, the upper end portions of the core layers CR may be located above the upper end portions of the channel layers CN.

As illustrated in FIG. 3E, a cap layer CPa covering the sidewall layers SW on the upper surface of the insulating layer 51 is formed. The cap layer CPa is an amorphous silicon layer or the like that is crystallized later to become the cap layer CP. The concave portions RCm at the upper end portions of the memory holes MH are also filled with the cap layer CPa.

As illustrated in FIG. 3F, the cap layer CPa and the sidewall layers SW are etched back and removed from the upper surface of the insulating layer 51. At this time, the over-etching amount is suppressed and controlled such that the cap layer CPa and the sidewall layers SW in the memory holes MH are not removed.

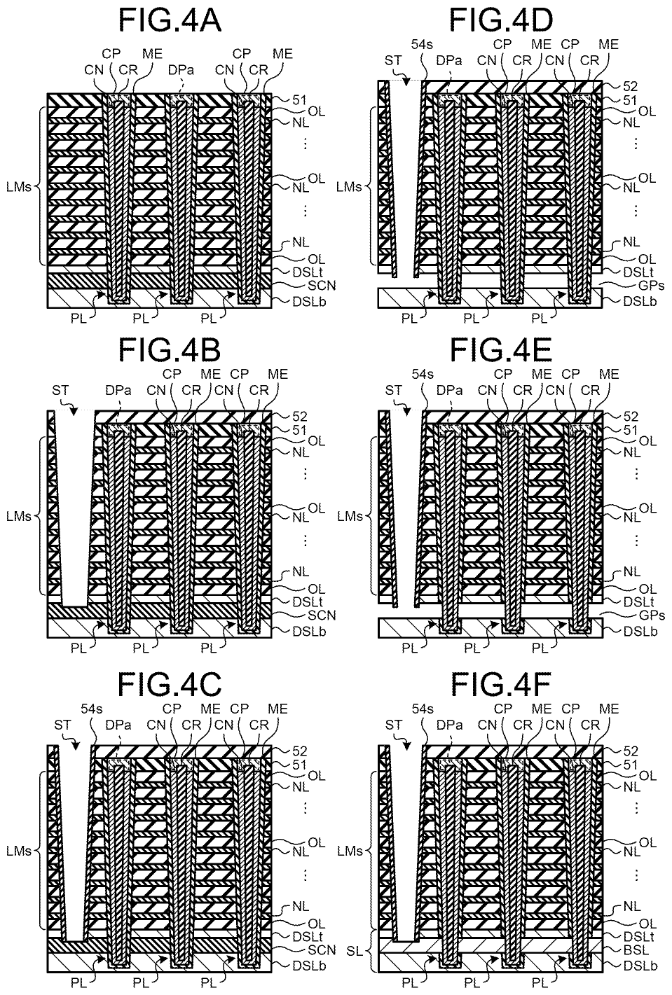

As illustrated in FIG. 4A, remaining cap layers CPa and sidewall layers SW are crystallized by, for example, annealing treatment or the like to form cap layers CP. The degree of crystallization in the cap layers CP may not be as high as that in the channel layers CN described above, and the cap layers CP may be, for example, polysilicon layers or the like. A layer of amorphous silicon may remain in part of the cap layers CP.

Note that, if the height position of the upper end portions of the core layers CR is, for example, below the uppermost insulating layer NL, the insides of the channel layers CN are filled with the cap layers CP at the height position of the uppermost insulating layer NL to be the select gate line SGD0 later, and the channel layers CN are not formed in annular shapes. As described above, since the upper end portions of the core layers CR protrudes from, for example, the upper end portions of the channel layers CN, such formation failure of the channel layers CN can be suppressed.

N-type dopant DPa such as arsenic is diffused into the formed cap layers CP. As described above, the dopant DPa may be, for example, an impurity such as phosphorus.

As a result, the pillars PL are formed. However, even at this point, the side surfaces and the lower end portions of the channel layers CN of the pillars PL are covered with the memory layers ME.

As illustrated in FIG. 4B, insulating layer 52 is formed on the insulating layer 51. In addition, a slit ST that penetrates the insulating layers 52 and 51, the stacked body LMs, and the upper source line DSLt and reaches the intermediate layer SCN is formed. The slit ST also extends in the direction along the X direction in the stacked body LMs.

As illustrated in FIG. 4C, insulating layers 54s are formed on the side walls of the slit ST facing each other in the Y direction. The insulating layers 54s are, for example, silicon oxide layers or the like, and serve as protective layers in a replacement process described later.

As illustrated in FIG. 4D, a removing liquid such as hot phosphoric acid is injected from the upper portion of the slit ST to remove the intermediate layer SCN exposed to the bottom surface of the slit ST. As a result, a gap GPs is formed between the upper source line DSLt and the lower source line DSLb, and the side surfaces of the memory layers ME on the outermost peripheries of the pillars PL are exposed in the gap GPs.

At this time, the removing liquid is suppressed from flowing into the stacked body LMs by the insulating layers 54s on the side walls of the slit ST, and the insulating layers NL in the stacked body LMs are not removed.

As illustrated in FIG. 4E, removing liquids for removing the silicon oxide layers, the silicon nitride layers, and the like are sequentially injected from the upper portion of the slit ST, and the block insulating layers BK, the charge trap layers CT, and the tunnel insulating layers TN are sequentially removed from the outer peripheral side of the memory layers ME exposed in the gap GPs. As a result, the side surfaces of the channel layers CN are exposed in the gap GPs.

As illustrated in FIG. 4F, a source material gas serving as a polysilicon or the like is injected from the upper portion of the slit ST, and the gap GPs is filled with a polysilicon layer or the like to form the intermediate source line BSL.

As a result, the source line SL including the lower source line DSLb, the intermediate source line BSL, and the upper source line DSLt is formed. In addition, the channel layers CN of the pillars PL are connected to the source line SL at the side surfaces.

Note that the process of removing the intermediate layer SCN to form the intermediate source line BSL as illustrated in FIGS. 4D to 4F is also referred to as a replacement process in the source line SL.

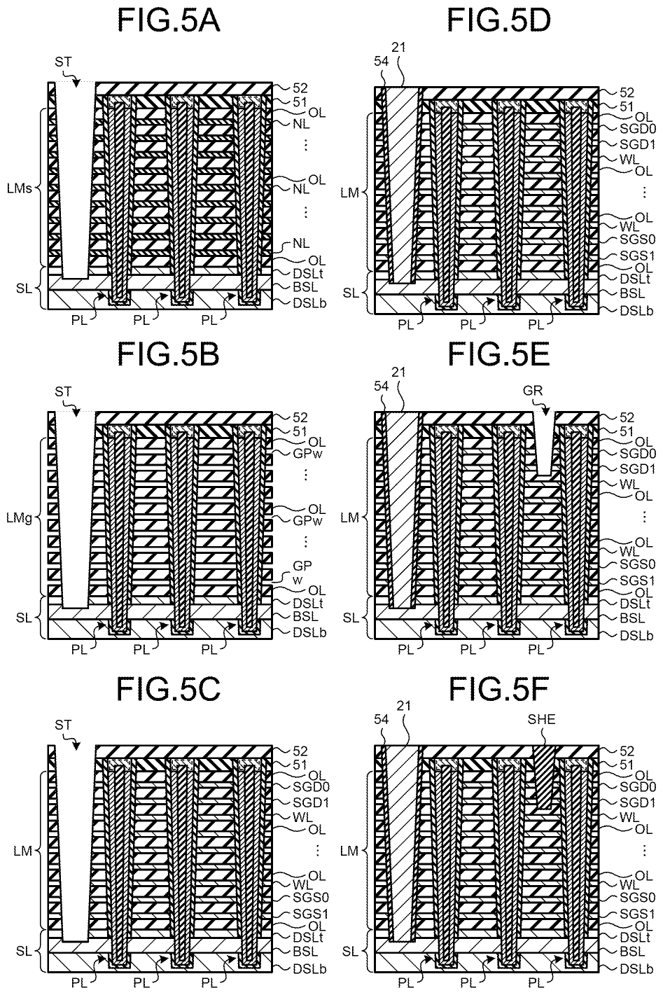

As illustrated in FIG. 5A, the insulating layers 54s on the side walls of the slit ST are removed.

As illustrated in FIG. 5B, a removing liquid such as hot phosphoric acid is injected from the upper portion of the slit ST to remove the insulating layers NL in the stacked body LMs exposed to the side surfaces of the slit ST. As a result, a stacked body LMg having gaps GPw between the plurality of insulating layers OL is formed.

As illustrated in FIG. 5C, a source material gas serving as a conductor or the like is injected from the upper portion of the slit ST, and the gaps GPw are filled with conductive layers to form the word lines WL and the select gate lines SGD and SGS. As a result, the stacked body LM in which the plurality of word lines WL and the plurality of select gate lines SGD and SGS are stacked is formed.

Note that the process of removing the insulating layers NL to form the word lines WL and the like as illustrated in FIGS. 5B to 5C is also referred to as a replacement process in the stacked body LM.

As illustrated in FIG. 5D, the insulating layers 54 are formed on the side walls of the slit ST, and the inside of the insulating layers 54 is filled with the conductive layer 21 to form a plate-like contact LI. However, the slit ST may be entirely filled with an insulating layer to form a plate-like member that does not function as a source line contact. In this case, the slit ST is formed exclusively for use in the replacement process of the source line SL and the stacked body LM.

As illustrated in FIG. 5E, in order to form the separation layer SHE, a groove GR that penetrates the insulating layers 52 and 51 and the select gate lines SGD0 and SGD1 and extends in the direction along the X direction is formed. In other words, of the conductive layers in the stacked body LM, the groove GR penetrates to the conductive layer desired to function as the select gate line SGD to separate them into the patterns of the plurality of select gate lines SGD.

As illustrated in FIG. 5F, the groove GR is filled with an insulating layer to form the separation layer SHE.

Thereafter, the insulating layer 53 is formed on the insulating layer 52, and the plug CH connected to the cap layer CP of the pillar PL penetrating the insulating layers 53 and 52, the bit line BL connected to the plug CH, and the like are formed.

As described above, the semiconductor memory device 1 according to the embodiment is manufactured.

(Overview)

In a semiconductor memory device such as a three-dimensional nonvolatile memory, there are issues of improving operation failures of memory cells due to a broad distribution of the threshold voltage, sensing failures of data due to small cell currents, and the like. In addition, there are also issues that the dopant diffused into the cap layers reaches, for example, the depth position of the select gates on the source side, and the off-characteristics of the select gates deteriorate or vary.

According to the semiconductor memory device 1 of the embodiment, the grain size of the crystal contained in the channel layers CN is larger than the grain size of the crystal contained in the cap layers CP, and the average grain size is, for example, 100 nm or more. As a result, the characteristics of the memory cells MC can be improved.

Specifically, by improving the crystallinity of the channel layers CN, the electrical resistance of the channel layers CN can be reduced, and the mobility of electrons as carriers can be improved. In addition, crystal defects in the channel layers CN can be reduced, and scattering and trapping of electrons are less likely to occur in the channel layers CN.

Since scattering and trapping of electrons in the channel layers CN are suppressed, the influence on the threshold voltage Vth between adjacent memory cells MC in the same pillar PL is reduced, the distribution of the threshold voltage Vth becomes steep, and the write characteristics can be improved.

In addition, the cell currents easily flow in the channel layers CN and are suppressed from attenuating in the channel layers CN. For this reason, the amount of cell currents flowing through the bit line BL increases and is easily sensed, and the read characteristics of the memory cells MC can be improved.

According to the semiconductor memory device 1 of the embodiment, two regions having different crystal grain sizes by the channel layers CN and the cap layers CP exist in the semiconductor layer, and the region having a larger crystal grain size extends at least from the height position of the uppermost select gate line SGD0 into the stacked body LM.

Here, the dopant DPa such as arsenic has a characteristic of diffusing along the grain boundary in the crystal. For this reason, diffusion of the dopant DPa toward the channel layers CN having high crystallinity and little influence of grain boundaries or the like is suppressed due to the interface segregation between the channel layers CN and the cap layers CP.

Thus, in the select gates STD, the off-characteristics and variation in the off-characteristics can be suppressed. In addition, since the select gates STD can be more reliably turned on/off, the reliability of the operations of the semiconductor memory device 1 can be guaranteed even if the number of select gates STD is reduced. Furthermore, it is also possible to increase the number of memory cells MC instead of the select gates STD to increase the memory capacity of the semiconductor memory device 1.

According to the semiconductor memory device 1 of the embodiment, the layer thickness of the channel layers CN covering the side surfaces of the core layers CR is, for example, 5 nm or less. As a result, the short channel effect can be suppressed.

According to the semiconductor memory device 1 of the embodiment, the memory layers ME cover the side surfaces and the lower end portions of the channel layers CN except for the depth position of the intermediate source line BSL in the source line SL, and the channel layers CN are connected to the source line SL at the side surfaces. By adopting such a connection scheme with the source line SL, the channel layers CNa can be crystallized in a state where the side surfaces and the lower end portions of the channel layers CNa are covered with the memory layers ME. As a result, the crystallinity of the channel layers CN can be further improved.

(Modification)

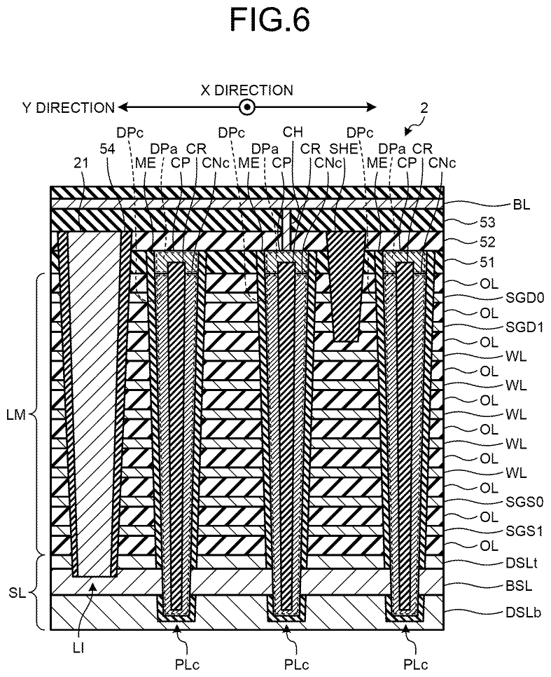

Next, a semiconductor memory device 2 according to a modification of the embodiment will be described with reference to FIG. 6. The semiconductor memory device 2 according to the modification is different from the above-described embodiment in that a predetermined dopant DPc is diffused in the channel layers CNc.

FIG. 6 is a cross-sectional diagram illustrating an example of a configuration of the semiconductor memory device 2 according to the modification of the embodiment. FIG. 6 illustrates a cross section along the Y direction similarly to FIG. 1A of the above-described embodiment. Note that, in FIG. 6, the same components as those of the semiconductor memory device 1 of the above-described embodiment are denoted by the same reference numerals, and the description thereof will be omitted.

As illustrated in FIG. 6, pillars PLc of the semiconductor memory device 2 include channel layers CNc extending in the stacking direction of the layers in the stacked body LM. Dopant DPc such as carbon is diffused in the crystal of the channel layers CNc. The volume density of the dopant DPc in the crystal of the channel layers CNc is, for example, 3×10¹⁸ atoms/cm³ or more and 5×10²⁰ atoms/cm³ or less.

However, the dopant DPc in the channel layers CNc may be an impurity such as oxygen or nitrogen other than carbon.

The configuration other than the above of the channel layers CNc and the configuration other than the above of the pillars PLc are the same as those of the channel layers CN and the pillars PL of the above-described embodiment.

The channel layers CNc containing the dopant DPc described above can be formed, for example, by diffusing the dopant DPc into the channel layers CNa at the timing when the channel layers CNa are formed in the memory holes MH and at the timing before the core layers CRs are formed in the process of FIG. 2C of the above-described embodiment.

According to the semiconductor memory device 1 of the modification, the dopant DPc of at least one of carbon, nitrogen, and oxygen is contained in the crystal of the channel layers CNc, and the volume density of the dopant DPc in the crystal is, for example, 3×10¹⁸ atoms/cm³ or more and 5×10²⁰ atoms/cm³ or less.

The dopant DPc such as carbon, nitrogen, and oxygen diffused into the channel layers CNc has an effect of suppressing diffusion of the dopant DPa such as arsenic diffused into the cap layers CP into the channel layers CNc. Thus, in the select gates STD, the off-characteristics and the variation in the off-characteristics can be further suppressed.

In addition, in the manufacturing process of the semiconductor memory device 2, by diffusing the dopant DPc such as carbon, nitrogen, or oxygen into the channel layers CNa before crystallization, an effect of promoting the crystallization of the channel layers CNa can also be expected.

According to the semiconductor memory device 2 of the modification, other effects similar to those of the semiconductor memory device 1 of the above-described embodiment are obtained.

(Other Modifications)

In the above-described embodiment and modification, the semiconductor memory devices 1 and 2 include the stacked body LM including the word lines WL and the select gate lines SGD and SGS, which are metal layers such as tungsten layers, as the conductive layers. However, the conductive layers of the stacked body may be layers containing a silicon material such as polysilicon layers. In this case, a stacked body in which layers containing a silicon material are stacked is formed from the beginning, and the semiconductor memory device is manufactured without including the replacement process.

In the above-described embodiment and modification, the semiconductor memory devices 1 and 2 have a one-tier (one-stage) structure including one stacked body LM. However, the semiconductor memory device may have a structure of two tiers or more.

In the above-described embodiment and modification, the semiconductor memory devices 1 and 2 include the peripheral circuit below or above the stacked body LM. However, the semiconductor memory device may include a peripheral circuit provided in the same layer as the stacked body.

In a case where the peripheral circuit is provided below the stacked body LM, the peripheral circuit including a transistor is formed on a semiconductor substrate such as a silicon substrate, and the source line SL, the stacked body LM, and the like are sequentially formed above the peripheral circuit, whereby the semiconductor memory devices 1 and 2 can be obtained.

In a case where the peripheral circuit is provided above the stacked body LM, the source line SL and the stacked body LM are formed on a support substrate, and a semiconductor substrate provided with the peripheral circuit is bonded above the stacked body LM, whereby the semiconductor memory devices 1 and 2 can be obtained.

In a case where the stacked body and the peripheral circuit are provided in the same layer, the stacked body can be formed on a semiconductor substrate, and the peripheral circuit can be formed at the outer edge portion thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of conductive layers and a plurality of insulating layers are alternately stacked; and
a pillar including a channel layer extending in a stacking direction of the plurality of conductive layers in the stacked body, a memory layer provided on a side surface of the channel layer, and a cap layer provided on the channel layer, the cap layer being connected to an upper layer wiring of the stacked body, wherein
the channel layer extends into the stacked body at least from a height position of an uppermost conductive layer of the plurality of conductive layers, and
a grain size of crystal contained in the channel layer is larger than a grain size of crystal contained in the cap layer.

2. The semiconductor memory device according to claim 1, wherein
an average grain size of the crystal in the channel layer is 100 nm or more.

3. The semiconductor memory device according to claim 1, wherein
the crystal of the channel layer contains at least one dopant of carbon, nitrogen, and oxygen.

4. The semiconductor memory device according to claim 3, wherein
a volume density of the dopant in the crystal of the channel layer is 3×10¹⁸ atoms/cm⁴ or more and 5×10²⁰ atoms/cm³ or less.

5. The semiconductor memory device according to claim 1, wherein
the crystal of the cap layer contains at least one dopant of arsenic and phosphorus.

6. The semiconductor memory device according to claim 1, wherein
the pillar includes a core material having insulating characteristics extending in the stacking direction, and
a layer thickness of the channel layer sandwiched between the memory layer and the core material is 5 nm or less.

7. The semiconductor memory device according to claim 6, wherein
a height position of an upper end portion of the core material is different from a height position of an upper end portion of the channel layer.

8. The semiconductor memory device according to claim 6, wherein
the upper end portion of the core material protrudes into the cap layer.

9. The semiconductor memory device according to claim 1, further comprising:
a conductive film extending in a direction along the plurality of conductive layers below the stacked body, wherein
a lower end portion of the pillar extends to the conductive film.

10. The semiconductor memory device according to claim 9, wherein
the channel layer is connected to the conductive film at the side surface.

11. The semiconductor memory device according to claim 10, wherein
the memory layer covers a lower end portion of the channel layer.

12. The semiconductor memory device according to claim 10, wherein
the memory layer covers the side surface and a lower end portion of the channel layer excluding a predetermined depth position in the conductive film.

13. The semiconductor memory device according to claim 1, further comprising:
a separation layer that penetrates at least the uppermost conductive layer of the plurality of conductive layers, extends in a first direction along the plurality of conductive layers, and separates the penetrated conductive layer in a second direction intersecting the first direction.

14. A semiconductor memory device comprising:
a stacked body in which a plurality of conductive layers and a plurality of insulating layers are alternately stacked; and
a pillar including a semiconductor layer extending in a stacking direction of the plurality of conductive layers in the stacked body, wherein
the semiconductor layer includes:
a first region reaching from a position higher than an uppermost conductive layer of the plurality of conductive layers to an upper end portion of the pillar; and
a second region extending at least from a height position of the uppermost conductive layer into the stacked body, the second region having a grain size of crystal contained in the semiconductor layer larger than a grain size of the crystal in the first region.

15. The semiconductor memory device according to claim 14, wherein
an average grain size of the crystal in the second region is 100 nm or more.

16. The semiconductor memory device according to claim 14, wherein
the crystal of the second region contains at least one dopant of carbon, nitrogen, and oxygen.

17. The semiconductor memory device according to claim 16, wherein
a volume density of the dopant in the crystal of the second region is 3×10¹⁸ atoms/cm³ or more and 5×10²⁰ atoms/cm³ or less.

18. The semiconductor memory device according to claim 14, wherein
the crystal of the first region contains at least one dopant of arsenic and phosphorus.

19. The semiconductor memory device according to claim 14, wherein
the pillar includes a core material having insulating characteristics extending in the stacking direction, and
a layer thickness of the semiconductor layer covering a side surface of the core material is 5 nm or less.

20. The semiconductor memory device according to claim 19, wherein
a height position of an upper end portion of the core material is different from a height position of a boundary portion between the first region and the second region.
